(19) United States
(12) Patent Application Publication
(10) Pub. No.: US 2026/0305427 A1
(43) Pub. Date: Oct. 1, 2026

(54) ELECTRONIC DEVICE HAVING AN INTEGRATED INDUCTOR COIL

(71) Applicant: TEXAS INSTRUMENTS INCORPORATED, DALLAS, TX (US)

(72) Inventors: Nicole YABUUCHI, ANGELES (PH); Charmaine Grace FACAL, OLONGAPO CITY (PH); John Carlo MOLINA, LIMAY (PH)

(21) Appl. No.: 19/093,591

(22) Filed: Mar. 28, 2025

(51) Int. Cl. H10W 70/69; H10W 44/00; H10W 70/02; H10W 70/04; H10W 70/40; H10W 74/01; H10W 74/10; H10W 90/00

(52) U.S. Cl. CPC H10W 70/69; H10W 44/501; H10W 70/023; H10W 70/041; H10W 70/417; H10W 70/424; H10W 74/016; H10W 74/10; H10W 90/724

(57) ABSTRACT

An electronic device includes a leadframe and a dielectric layer formed around the leadframe. A die and an inductor coil are attached to the leadframe. A heat resistive adhesive is disposed on a portion of the coil and a mold compound is formed over the die and the coil. The heat resistive adhesive inhibits expansion of the coil during high temperature processing during fabrication of the electronic device.

### TECHNICAL FIELD

The present disclosure relates to an electronic device and more specifically, to an electronic device package that includes an integrated inductor coil and a heat resistant adhesive.

### BACKGROUND

Over-molded power modules include integrated passive components and an inductor coil encased in a mold compound. Over-molded power modules are configured to provide a small footprint and reduce the design time and complexity since the inductor coil and other passive components are integrated into the package. In addition, over-molded power modules inherently reduce EMI affects due to the integration of the inductor coil and passive components. Still further, power modules include a thermally conductive baseplate that provides thermal dissipation to remove heat generated by the components of the power module.

### SUMMARY

In described examples, an electronic device includes a leadframe and a die attached to the leadframe. A coil is attached to the leadframe, where the coil includes an expansion inhibiting mechanism disposed on a portion of the coil. A mold compound is formed over the die and the coil.

In another described example, a power module includes a leadframe and a dielectric layer formed around the leadframe. A die is attached to the leadframe and a coil is attached to the leadframe, where the coil includes a heat resistive material disposed on a portion of the coil. A mold compound is formed over the die and the coil.

In still another described example, a method includes attaching a die to a leadframe and attaching a coil to the leadframe. A heat resistive material is deposited on a portion of the coil and a mold compound is formed over the die and the coil.

### BRIEF DESCRIPTION OF THE DRAWINGS

FIG. 1A is a cross section view of an example electronic device.

FIG. 1B is a perspective view of an example inductor coil.

FIG. 2 is a block diagram flow chart illustrating a fabrication process for the electronic device of FIG. 1A.

FIG. 3A illustrates a cross sectional view of a leadframe in the early stages of fabrication of an example electronic device.

FIG. 3B illustrates a cross sectional view of a leadframe of FIG. 3A after formation of a dielectric layer.

FIG. 3C illustrates a cross sectional view of the leadframe of FIG. 3B after undergoing deposition of interconnects on the leadframe.

FIG. 3D illustrates a cross sectional view of the leadframe of FIG. 3C after placement of a die on the leadframe.

FIG. 3E illustrates a cross sectional view of the leadframe and die of FIG. 3D after placement of a coil on the leadframe.

FIG. 3F illustrates a cross sectional view of the leadframe and die of FIG. 3E deposition of an adhesive on the coil.

FIG. 3G illustrates a cross sectional view of the leadframe and die of FIG. 3F after undergoing a reflow process.

FIG. 3H illustrates a cross sectional view of the leadframe based substrate of FIG. 3G after undergoing formation of a mold compound.

### DETAILED DESCRIPTION

Over-molded power modules include integrated passive components and an inductor coil encased in a mold compound. Over-molded power modules are configured to provide a small footprint and reduce the design time and complexity since the inductor coil and other passive components are integrated into the package. In addition, over-molded power modules inherently reduce EMI affects due to the integration of the inductor coil and passive components. Still further, power modules include a thermally conductive baseplate that provides thermal dissipation to remove heat generated by the components of the power module.

During fabrication, however, the inductor coil can be displaced during a reflow process. Specifically, during the reflow process after the inductor coil is attached to a leadframe, the inductor coil tends to expand, which causes the inductor coil to shift and/or rotate with respect to the leadframe. This in turn adversely affects downstream processes such as molding and singulation. For example, since the inductor coil is misaligned, the inductor coil may overlap into the saw street. Thus, during singulation, the inductor coil can be damaged by a cutting device (e.g., laser, dicing saw, etc.) thereby ultimately leading to device failure.

Disclosed herein is an electronic device that includes an integrated inductor coil and a heat resistive material (e.g., an adhesive) disposed on the inductor coil that overcomes the aforementioned disadvantages. The heat resistive material is disposed on a top of the inductor coil and stabilizes the inductor coil during high temperature downstream processes. Specifically, as mentioned above, the inductor coil can expand and shift during high temperature downstream processes, (e.g., reflow). The heat resistive material is configured to withstand the high temperature processes and thus stabilizes the inductor coil by inhibiting expansion of the inductor coil during the high temperature processes. As a result, the inductor coil is less prone to shift with respect to the leadframe. Thus, further downstream processes (e.g., singulating, molding) can be performed without damaging the inductor coil.

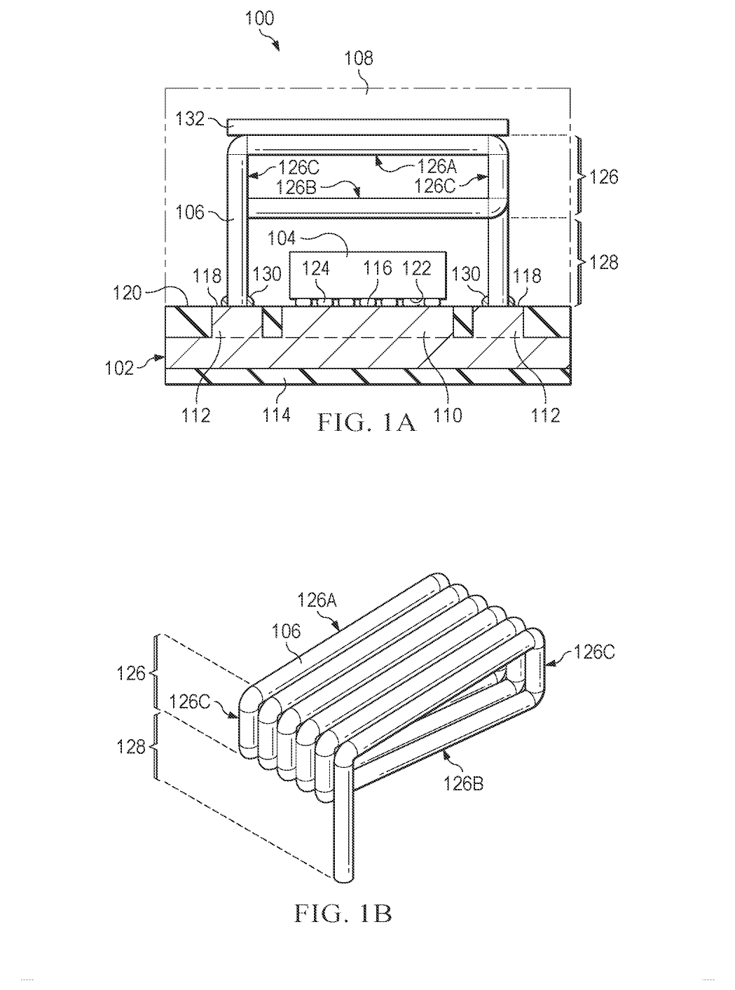

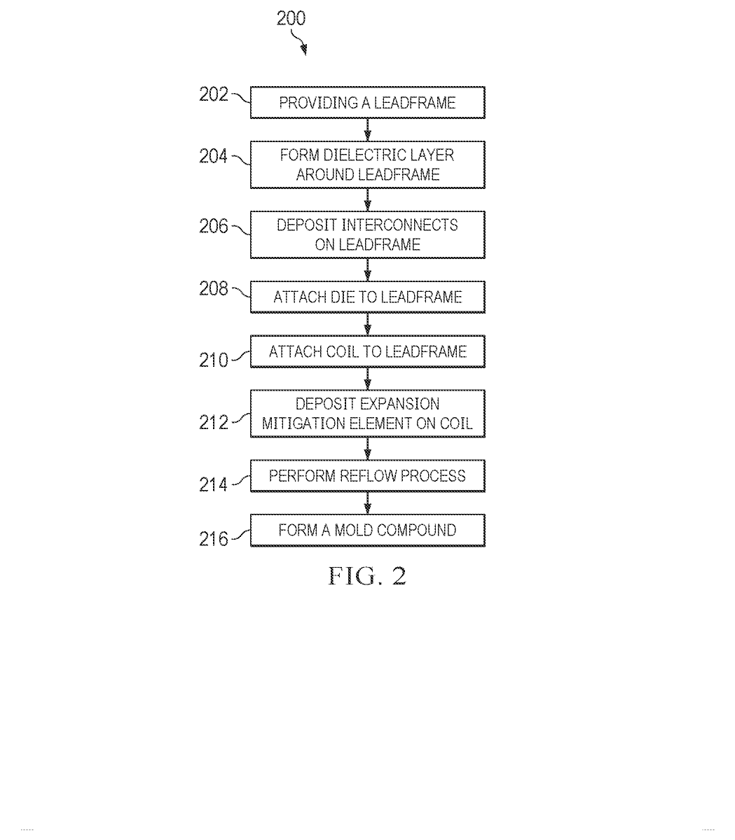

FIG. 1A is a cross-sectional view of an electronic device (e.g., integrated circuit (IC) 100 that includes a leadframe 102, a die 104 disposed on the leadframe 102, an integrated coil (e.g., inductor coil) 106 disposed on the leadframe 102, and a mold compound 108 that encapsulates the die 104 and the coil 106. The example electronic device 100 in FIG. 1A is an example illustration of a QFN package. The electronic device 100, however, can be comprised of a leaded or non-leaded integrated circuit (IC) including, but not limited to a Quad Flat No-Lead (QFN) package, a Quad-Flat Package (QFP), Dual In-Line Package (DIP), Single In-Line Package (SIP), Small Outline Package (SOP), etc. In addition, the electronic device may further include other electronic components (e.g., dies, transistors, resistors, capacitors, etc.). Thus, the electronic device 100 illustrated in FIG. 1A is for illustrative purposes only and is not intended to limit the scope of the invention.

The leadframe 102 includes a die attach pad 110 and coil attach pads 112. A dielectric layer (e.g., Ajinomoto Build Up Film (ABF)) 114 is formed around the leadframe 102 such that a first (exposed) surface 116 of the die attach pad 110 and a first (exposed) surface 118 of the coil attach pads 112 are substantially flush with a first surface 120 of the dielectric layer 114. In the example illustrated in FIG. 1A, the die 104 is a flip-chip type die 104 that includes an active side 122. The active side 122 of the die 104 attaches to the first surface 116 of the die attach pad 110 via solder interconnects 124. It is to be understood, however, that the die 104 can be a non-flip-chip type die, where a non-active side of the die 104 can attach to the die attach pad 110 and wire bonds can be attached from the active side 122 to the leadframe 102.

The coil 106 is a continuous coil and includes a coil portion 126 and attachment (support) portions 128 that extend from the coil portion 126. The coil portion 126 is comprised of multiple continuous windings (e.g., 3-12 windings). For example, FIG. 1B is an example illustration of a coil 106 having five coils. The coil portion 126 includes an upper section (coils) 126A, a lower section (coils) 126B, and side sections (coils) 126C that join the upper and lower sections 126A, 126B. The coil 106 functions as an energy storage device, primarily used to smooth out current fluctuations by temporarily storing electrical energy in a magnetic field and releasing it back into the circuit when needed. Thus, the coil 106 maintains a stable output voltage, especially in switching power supplies where current changes rapidly. The attachment portions 128 attach to the coil attach pads 112 on the leadframe 102 via interconnects 130 (e.g., solder paste, solder balls, etc.). Thus, the die 104 is situated below the coil 106 such that the die 104 is disposed between the attachment portions 128.

A heat resistive material (e.g., an adhesive (e.g., epoxy)) 132 is disposed on a top outer surface of the coil portion 126 of the coil 106. The heat resistive material 132 inhibits expansion of the coil 106 while undergoing high temperature downstream processes, such as reflow, where the temperature exceeds approximately 130°C. Thus, the heat resistive material 132 act as a stabilizer for the coil 106 during the high temperature downstream processing. As a result, the coil 106 is less prone to shift with respect to the leadframe 102 during the high temperature downstream processes. Thus, the heat resistive material 132 functions as an expansion inhibiting mechanism for the coil 106. Therefore, further downstream processes (e.g., singulating, molding) can be performed without damaging the coil 106.

In the example illustrated in FIGS. 1A and 1B, the heat resistive material 132 is formed only on a top outer surface of the upper section 126A of the coil portion 126. In other examples, however, the heat resistive material 132 may be formed around an entire outer surface of each individual coil of the upper section 126A and/or of the lower section 126B and/or the side sections 126C that join the upper and lower coils 126A, 126B. In still yet another example, the heat resistive material 132 may also be formed on an outer surface of the attachment portions 128 that faces away from the die 104 or around the entire outer surface of the attachment portions 128 of the coil 106. Finally, the heat resistive material 132 may be formed on or around the coil 106 in any combination of the above.

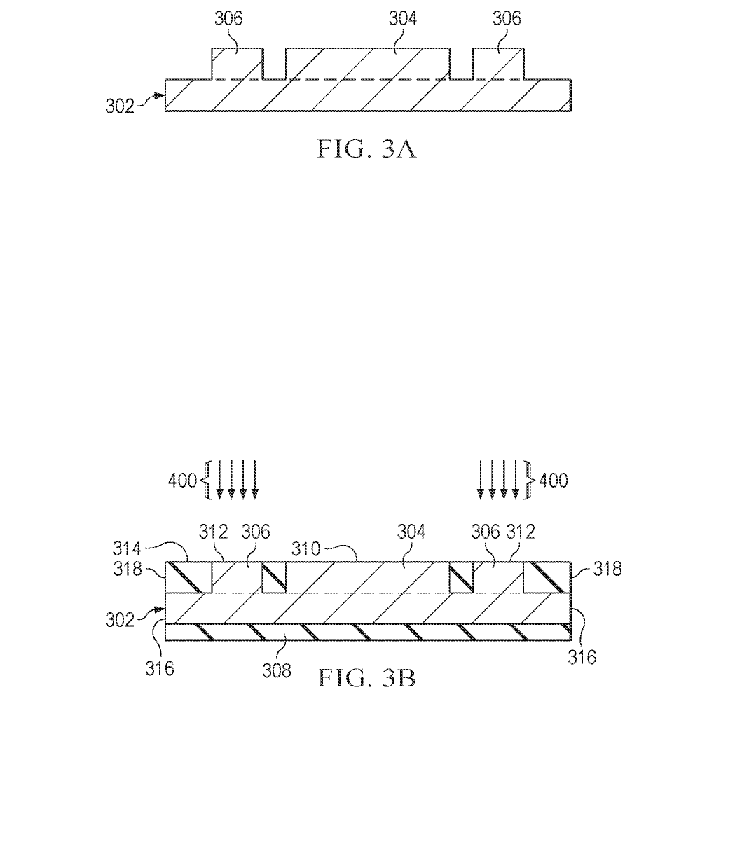

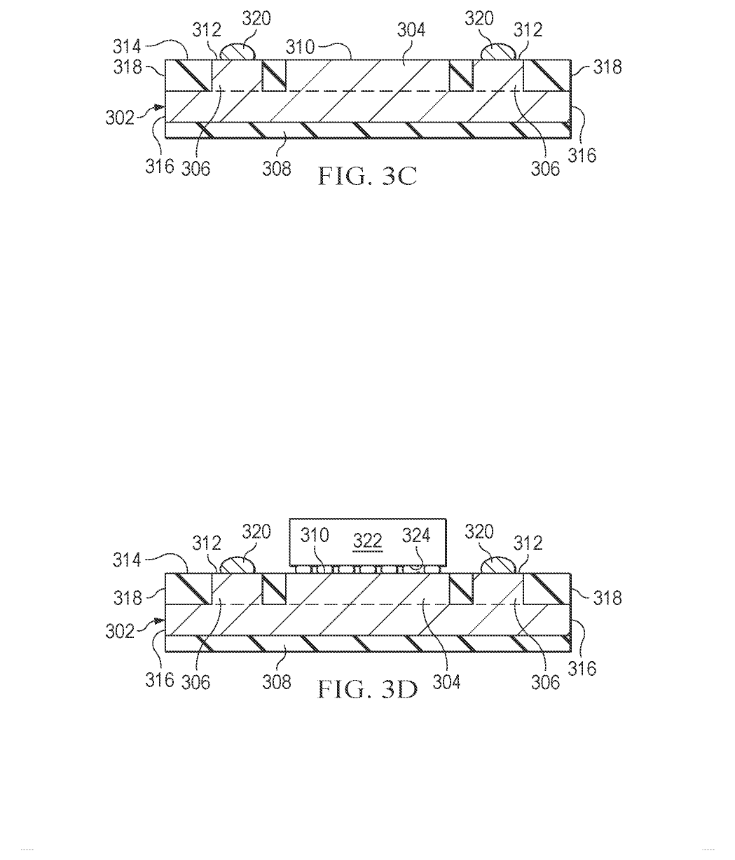

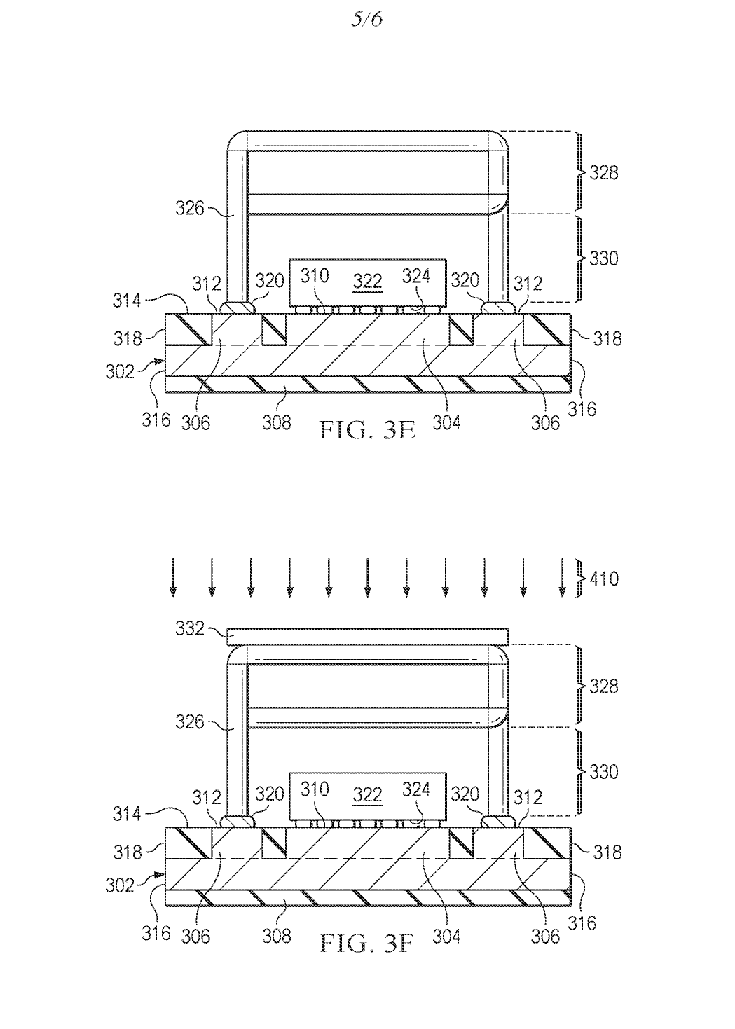

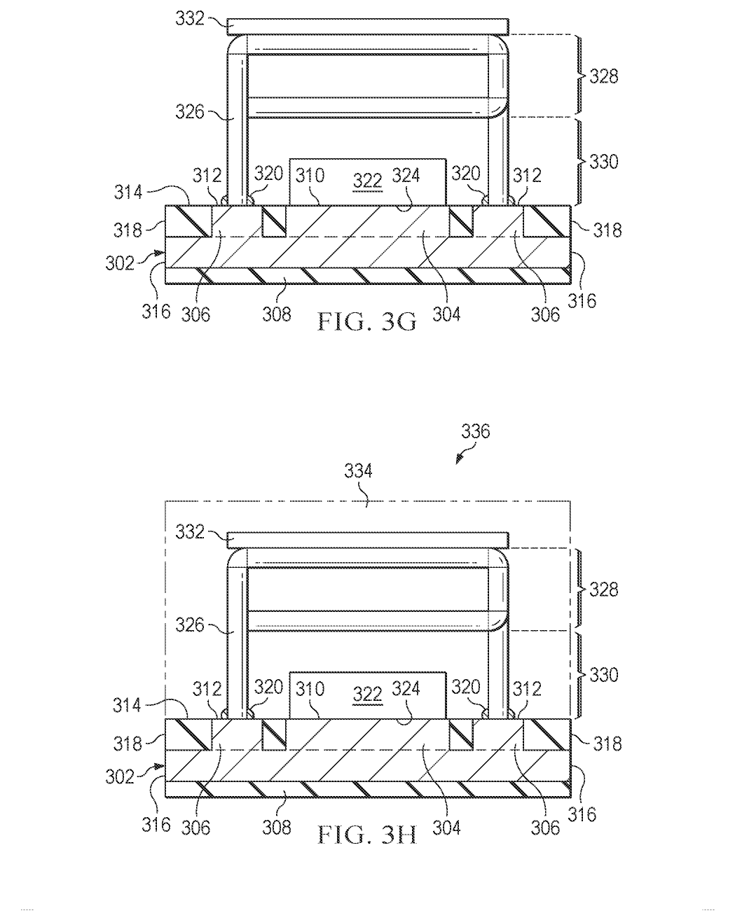

FIG. 2 is a block diagram flow chart explaining a fabrication process 200 and FIGS. 3A-3H illustrate a fabrication process associated with the formation of the electronic device 100 illustrated in FIG. 1A. Though depicted sequentially as a matter of convenience, at least some of the actions shown can be performed in a different order and/or performed in parallel. Alternatively, some implementations may perform only some of the actions shown. Still further, although the example illustrated in FIGS. 2 and 3A-3H is an example method illustrating the example configuration of FIG. 1A, other methods and configurations are possible. It is understood that although the method illustrated in FIGS. 2 and 3A-3H depicts the fabrication process of a single electronic device, the process applies to an array electronic devices. Thus, after fabrication of the array of electronic devices the array is singulated to separate each electronic device 100 from the array.

Referring to FIGS. 2 and to 3A-3H, the fabrication process of the electronic device 100 begins at 202 with leadframe 302, as illustrated in FIG. 3A. The leadframe 302 includes a die attach pad 304 and coil attach pads 306. At 204, the leadframe 302 undergoes a pre-mold where a dielectric layer (e.g., ABF) 308 is formed around the leadframe 302 resulting in the configuration of FIG. 3B. First surfaces 310, 312 of both the die attach pad 304 and the coil attach pads 306 respectively are substantially flush with a first surface 314 of the dielectric layer 308. In addition, side surfaces 316 of the leadframe 302 are substantially flush with side surfaces 318 of the dielectric layer 308. Thus, the side surfaces 316 of the leadframe 302 function as contacts or terminals that come in contact with an external electronic/electrical device when installed on, in, or adjacent to the external electronic/electrical device.

At 206, the configuration of FIG. 3B undergoes a deposition (e.g., screenprint) process 400 to deposit interconnects (e.g., solder paste, solder balls, etc.) 320 on the first surfaces 312 of the coil attach pads 306 resulting in the configuration of FIG. 3C. At 208, a die 322 is disposed on the first surface 310 of the die attach pad 304 such that an active side 324 of the die 322 is attached to the first surface 310 of the die attach pad 304 via solder balls resulting in the configuration of FIG. 3D. At 210, a coil (e.g., inductor coil) 326 is attached to the coil attach pads 306 via the interconnects 320 resulting in the configuration of FIG. 3E. Specifically, the coil 326 includes a coil portion 328 comprised of multiple windings (e.g., 3-12 windings), which functions as an energy storage device, and attachment (support) portions 330. The attachment portions 330 attach to the coil attach pads 306 on the leadframe 302 via the interconnects 320. Thus, the die 322 is situated below the coil portion 328 such that the die 322 is disposed between the attachment portions 330.

At 212, a heat resistive material (e.g., an adhesive (e.g., epoxy)) 332 is disposed on the coil portion 328 of the coil 326 resulting in the configuration of FIG. 3F. The heat resistive material 332 inhibits expansion of the coil 326 while undergoing high temperature downstream processes, such as reflow. Thus, the heat resistive material 332 act as a stabilizer (e.g., expansion inhibiting mechanism) for the coil 326 during the high temperature downstream processing. As a result, the coil 326 is less prone to shift with respect to the leadframe 302 during the high temperature downstream processing. Thus, further downstream processes (e.g., singulating, molding) can be performed without damaging the coil 326.

At 214, the configuration of FIG. 3F undergoes a reflow process 410 to form joints between the die 322 and the die attach pad 304 of the leadframe 302 and between the attachment portions 330 of the coil 326 and the coil attach pads 306 of the leadframe 302 resulting in the configuration of FIG. 3G. The reflow temperature ranges from approximately 150°C to 270°C. At 216, a mold compound 334 is formed over the die 322 and the coil 326 thereby encapsulating the die 322 and the coil 326 resulting in the electronic device 336 illustrated in the configuration of FIG. 3H. In the illustrated example, the mold compound 334 extends toward the dielectric layer 308 and contacts the first surface 314 of the dielectric layer 308.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a leadframe;
a die attached to the leadframe;
a coil attached to the leadframe, the coil including an expansion inhibiting mechanism disposed on a portion of the coil; and
a mold compound formed over the die and the coil.

2. The electronic device of claim 1, wherein the expansion inhibiting mechanism is formed on only a top outer surface of the coil.

3. The electronic device of claim 1, wherein the expansion inhibiting mechanism is an adhesive configured to inhibit expansion of the coil when the coil is subjected to temperatures exceeding approximately 130°C.

4. The electronic device of claim 1 further comprising a dielectric layer formed over the leadframe.

5. The electronic device of claim 4, wherein the leadframe includes a die attach pad and coil attach pads, and wherein a first surface of the die attach pad and a first surface of the coil attach pads are substantially flush with a first surface of the dielectric layer.

6. The electronic device of claim 5, wherein an active side of the die is attached to the first surface of the die attach pad via solder interconnects.

7. The electronic device of claim 6, wherein the coil includes a coil portion and attachment portions, wherein the attachment portions are attached to the first surface of the coil attach pads via interconnects.

8. The electronic device of claim 7, wherein the die is disposed below the coil portion and between the attachment portions of the coil.

9. A power module comprising:
a leadframe;
a dielectric layer formed around the leadframe;
a die attached to the leadframe;
a coil attached to the leadframe, the coil including a heat resistive material disposed on a portion of the coil; and
a mold compound formed over the die and the coil.

10. The power module of claim 9, wherein the heat resistive material is formed on only a top outer surface of the coil.

11. The power module of claim 9, wherein the heat resistive material is an adhesive configured to inhibit expansion of the coil when the coil is subjected to temperatures exceeding approximately 130°C.

12. The power module of claim 9, wherein the leadframe includes a die attach pad and coil attach pads, wherein a first surface of the die attach pad and a first surface of the coil attach pads are substantially flush with a first surface of the dielectric layer.

13. The power module of claim 12, wherein an active side of the die is attached to the first surface of the die attach pad via solder interconnects.

14. The power module of claim 13, wherein the coil includes a coil portion and attachment portions, wherein the attachment portions are attached to the first surface of the coil attach pads via interconnects.

15. The power module of claim 14, wherein the die is disposed below the coil portion and between the attachment portions of the coil.

16. A method comprising:
attaching a die to a leadframe;
attaching a coil to the leadframe;
depositing a heat resistive material on a portion of the coil; and
forming a mold compound over the die and the coil.

17. The method of claim 16, wherein depositing a heat resistive material on a portion of the coil includes depositing a heat resistive adhesive on only a top outer surface of the coil, the heat resistive adhesive configured to inhibit expansion of the coil when the coil is subjected to temperatures exceeding approximately 130°C.

18. The method of claim 16, wherein prior to attaching a die to the leadframe, the method comprising forming a dielectric layer around the leadframe.

19. The method of claim 18, wherein attaching a coil to the leadframe includes attaching attachment portions of the coil to coil attach pads on the leadframe.

20. The method of claim 19, wherein prior to forming a mold compound over the die and the coil, the method comprising performing a reflow process in a temperature range of approximately 150°C to 270°C.
